(19) United States
(12) Patent Application Publication
(10) Pub. No.: US 2023/0245978 A1
(43) Pub. Date: Aug. 3, 2023

(54) SHIELDED WAFER LEVEL CHIP SCALE PACKAGE WITH SHIELD CONNECTED TO GROUND WITH VIAS THROUGH DIE

(71) Applicant: Skyworks Solutions, Inc., Irvine, CA (US)

(72) Inventors: Sundeep Nand Nangalia, Raleigh, NC (US); Reza Kasnavi, Solana Beach, CA (US); William Gerard Vaillancourt, Methuen, MA (US); Gregory Edward Babcock, Ottawa (CA)

(21) Appl. No.: 18/162,481

(22) Filed: Jan. 31, 2023

Related U.S. Application Data
(60) Provisional application No. 63/305,387, filed on Feb. 1, 2022.
(60) Provisional application No. 63/305,397, filed on Feb. 1, 2022.
(60) Provisional application No. 63/305,384, filed on Feb. 1, 2022.

(51) Int. Cl. H01L 23/552; H01L 23/48; H01L 23/498; H01L 23/36

(52) U.S. Cl. CPC H01L 23/552; H01L 23/481; H01L 23/49822; H01L 23/49816; H01L 23/36

(57) ABSTRACT

An electronics package for use in a module of an electronic device has a die, and a plurality of interconnect members disposed under the die. One or more vias extend through the die and electrically connect to the interconnect members. A metal shield is disposed over the die. The metal shield is in contact with a peripheral boundary of the die and connected to ground with the vias and the interconnect members. The metal shield shields the die from stray power and electromagnetic radiation.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

Embodiments of this disclosure relate to wafer level chip scale packages and, more specifically, to shielded wafer level chip scale packages.

### Description of Related Technology

Radio frequency (RF) devices can be used for transmitting and/or receiving signals of a wide range of frequencies. For example, an RF devices can be used to wirelessly communicate RF signals in a frequency range of electromagnetic radiation typically used to produce and detect radio waves. Such a range can be from about 30 kHz to 300 GHz. In some situations, operation of an electronic device can adversely affect and/or be adversely affected by undesired RF signals.

Electromagnetic (EM) fields generated by radio frequency devices can interfere with (e.g., result in EM interference) or diminish the performance of other circuitry, as well as diminish the performance of wireless devices that use such an RF device.

### SUMMARY

In accordance with one aspect of the disclosure, an electronics package for use in a module of an electronic device is provided. The electronics package comprises a die, a substrate disposed under and attached to the die, the substrate including one or more redistribution layers, and a plurality of interconnect members disposed under and attached to the substrate, the interconnect members electrically connected to the die via the redistribution layers in the substrate. A metal shield is disposed over the die, the metal shield in contact with a peripheral boundary of the substrate and connected to ground via the plurality of interconnect members. The metal shield is configured to shield the die from stray power and electromagnetic radiation.

In accordance with another aspect of the disclosure, a module for an electronic device is provided. The module comprises a package substrate and an electronics package mounted on the package substrate. The electronics package includes a die, a substrate disposed under and attached to the die, the substrate including one or more redistribution layers, and a plurality of interconnect members disposed under and attached to the substrate, the interconnect members electrically connected to the die via the redistribution layers in the substrate. A metal shield is disposed over the die, the metal shield in contact with a peripheral boundary of the substrate and connected to ground via the plurality of interconnect members. The metal shield is configured to shield the die from stray power and electromagnetic radiation. The electronics package is mounted to the package substate via the interconnect. The module also comprises additional circuitry, the electronics package and additional circuitry disposed on the package substrate.

In accordance with another aspect of the disclosure, a wireless electronic device is provided. The wireless electronic device comprises an antenna and a front end module including one or more electronics packages. Each electronics package includes a die, a substrate disposed under and attached to the die, the substrate including one or more redistribution layers, and a plurality of interconnect members disposed under and attached to the substrate, the interconnect members electrically connected to the die via the redistribution layers in the substrate. A metal shield is disposed over the die, the metal shield in contact with a peripheral boundary of the substrate and connected to ground via the plurality of interconnect members. The metal shield is configured to shield the die from stray power and electromagnetic radiation.

In accordance with another aspect of the disclosure, a method of manufacturing an electronics package for use in a module of an electronic device is provided. The method comprises forming or providing a substrate including one or more redistribution layers, forming or providing a die and attaching the die to one side of the substrate. The method also comprises forming or providing a plurality of interconnect members on an opposite side of the substrate, the interconnect members electrically connected to the die via the redistribution layers in the substrate. The method also comprises forming a metal shield over the die and extending over a peripheral boundary of the substrate so that the metal shield covers the die and at least a portion of the peripheral boundary of the substrate, the shield connected to ground via the plurality of interconnect members. The metal shield is configured to shield the die from stray power and electromagnetic radiation.

In accordance with another aspect of the disclosure, an electronics package for use in a module of an electronic device is provided. The electronics package comprises a die, a plurality of interconnect members disposed under the die, and one or more vias that extend through the die and are electrically and thermally connected to one of more of the interconnect members. A metal shield is disposed over the die, the metal shield in contact with a peripheral boundary of the die and connected to ground via the one or more vias and the interconnect members. The metal shield is configured to shield the die from stray power and electromagnetic radiation.

In accordance with another aspect of the disclosure, a module for an electronic device is provided. The module comprises a package substrate and an electronics package mounted on the package substrate. The electronics package includes a die, a plurality of interconnect members disposed under the die, and one or more vias that extend through the die and are electrically and thermally connected to one of more of the interconnect members. A metal shield is disposed over the die, the metal shield in contact with a peripheral boundary of the die and connected to ground via the one or more vias and the interconnect members. The metal shield is configured to shield the die from stray power and electromagnetic radiation. The electronics package is mounted to the package substate via the interconnect members. The module also comprises additional circuitry, the electronics package and additional circuitry disposed on the package substrate.

In accordance with another aspect of the disclosure, a wireless electronic device is provided. The wireless electronic device comprises an antenna and a front end module including one or more electronics packages. Each electronics package includes a die, a plurality of interconnect members disposed under the die, and one or more vias that extend through the die and are electrically and thermally connected to one of more of the interconnect members. A metal shield is disposed over the die, the metal shield in contact with a peripheral boundary of the die and connected to ground via the one or more vias and the interconnect members. The metal shield is configured to shield the die from stray power and electromagnetic radiation.

In accordance with another aspect of the disclosure, a method of manufacturing an electronics package for use in a module of an electronic device is provided. The method comprises forming or providing a die, forming one or more vias through the die, and forming or providing a plurality of interconnect members under the die, the interconnect members electrically and thermally connected to the one or more vias. The method also comprises forming a metal shield over the die and extending over a peripheral boundary of the die so that the metal shield covers the die, the shield connected to ground via the one or more vias and the plurality of interconnect members. The metal shield is configured to shield the die from stray power and electromagnetic radiation, the one or more vias configured to dissipate heat from the metal shield and the die.

In accordance with another aspect of the disclosure, an electronics package for use in a module of an electronic device is provided. The electronics package comprises, a die, a plurality of interconnect members disposed under the die, and a seal ring that extends along an outer boundary of the die. A metal shield is disposed over the die, the metal shield in contact with a peripheral boundary of the die and connected to ground via the seal ring and the plurality of interconnect members. The metal shield is configured to shield the die from stray power and electromagnetic radiation.

In accordance with another aspect of the disclosure, a module for an electronic device is provided. The module comprises a package substrate and an electronics package mounted on the package substrate. The electronics package includes a die, a plurality of interconnect members disposed under the die, and a seal ring that extends along an outer boundary of the die. A metal shield is disposed over the die, the metal shield in contact with a peripheral boundary of the die and connected to ground via the seal ring and the plurality of interconnect members. The metal shield is configured to shield the die from stray power and electromagnetic radiation. The electronics package is mounted to the package substate via the interconnect. The module also comprises additional circuitry, the electronics package and additional circuitry disposed on the package substrate.

In accordance with another aspect of the disclosure, a wireless electronic device is provided. The wireless electronic device comprises an antenna and a front end module including one or more electronics packages. Each electronics package includes a die, a plurality of interconnect members disposed under the die, and a seal ring that extends along an outer boundary of the die. A metal shield is disposed over the die, the metal shield in contact with a peripheral boundary of the die and connected to ground via the seal ring and the plurality of interconnect members. The metal shield is configured to shield the die from stray power and electromagnetic radiation.

In accordance with another aspect of the disclosure, a method of manufacturing an electronics package for use in a module of an electronic device is provided. The method comprises forming or providing a die, forming a seal ring that extend along an outer boundary of the die, and forming or providing a plurality of interconnect members under the die. The method also comprises forming a metal shield over the die and extending over a peripheral boundary of the die so that the metal shield covers the die, the shield connected to ground via the seal ring and the plurality of interconnect members. The metal shield is configured to shield the die from stray power and electromagnetic radiation.

### BRIEF DESCRIPTION OF THE DRAWINGS

Embodiments of this disclosure will now be described, by way of non-limiting example, with reference to the accompanying drawings.

FIG. 1 is a schematic view of a dual sided package with various electronic components.

FIG. 2 is a schematic view of a shielded wafer level chip scale package.

FIG. 3 is a schematic view of a shielded wafer level chip scale package.

FIG. 3A is a schematic view of a shielded wafer level chip scale package.

FIG. 4 is a schematic view of a shielded wafer level chip scale package.

FIG. 4A is a schematic view of a shielded wafer level chip scale package.

FIGS. 5A-5C are schematic illustrations of steps in the manufacturing of the shielded wafer level chip scale package of FIG. 2.

FIG. 5D is a top view of a portion of a wafer of chip scale packages during a step in the manufacturing process for the shielded wafer level chip scale package of FIG. 2.

FIG. 5E is a schematic illustrations of a step in the manufacturing of the shielded wafer level chip scale package of FIG. 2.

FIG. 5F is an enlarged view of the shielded wafer level chip scale package of FIG. 5E.

FIGS. 6A-6C are schematic illustrations of steps in the manufacturing of the shielded wafer level chip scale package of FIG. 2.

FIG. 7A is a schematic illustration of a steps in the manufacturing of the shielded wafer level chip scale package of FIG. 4.

FIG. 7B is a partial schematic top view of a street between wafer level chip scale packages during a step in the manufacturing of the shielded wafer level chip scale package of FIG. 4.

FIGS. 7C-7D are schematic illustrations of steps in the manufacturing of the shielded wafer level chip scale package of FIG. 4.

FIGS. 8A-8C are schematic illustrations of steps in the manufacturing of the shielded wafer level chip scale package of FIG. 3.

FIG. 9 shows one or more of modules that are mounted on a wireless phone board that can include one or more features described herein.

FIG. 10 schematically depicts the circuit board with the shielded wafer level chip scale package installed thereon.

FIG. 11 schematically depicts a wireless device having the circuit board with the shielded wafer level chip scale package installed thereon.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

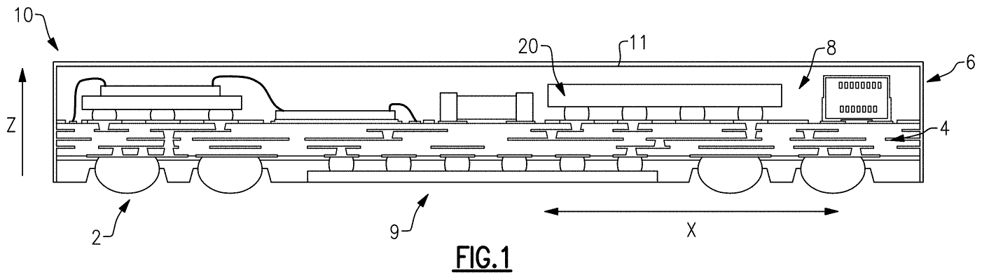

FIG. 1 shows a dual sided package 10 with one or more (a plurality of) solder connections (e.g., balls, or other electrical interconnect members) 2 that are connected to an underside of a printed circuit board (PCB) 4. A plurality of electronic components 6 are connected to a top side of the PCB 4, including a wafer level chip scale package (WLCSP) 20. Overmold 8 can be disposed over the electronic components 6, including the WLCPS 20. A shield 11 is disposed over the overmold 8 to shield all of the electronic components 6 from electromagnetic (EM) interference from components outside the shield 11. The package 10 can be mounted on a phone board or motherboard of an electronic device.

However, in some instances, it may be preferable to shield only one (or only a few) of the electrical component (e.g., the WLCSP 20), rather than shielding the entire package 10, which is not contemplated in the package 10. Doing so would advantageously facilitate (e.g., allow) a reduction in the size of the package 10 in the height or Z directions, as the overmold 8 and/or shield 11 could be excluded from the package 10. Additionally, such shielding of specific electrical components (as compared to the whole package 10), such as shielding the WLCSP 20, would advantageously facilitate (e.g., allow) a reduction in the size of the package in the width or X direction and depth or Y direction (into the page in FIG. 1) as the electronic components 6 could be arranged closer to each other while inhibiting EM interference between them (e.g., due to the component(s), such as the WLCSP 20 being shielded). Further, such shielding of individual components (e.g., of WLCSP 20) advantageously reduces the cost of manufacturing because, for example, the overmold 8 and shield 11 could be excluded (reducing material cost) and the steps for forming or applying the overmold 8 and shield 11 would be excluded (reducing processing time).

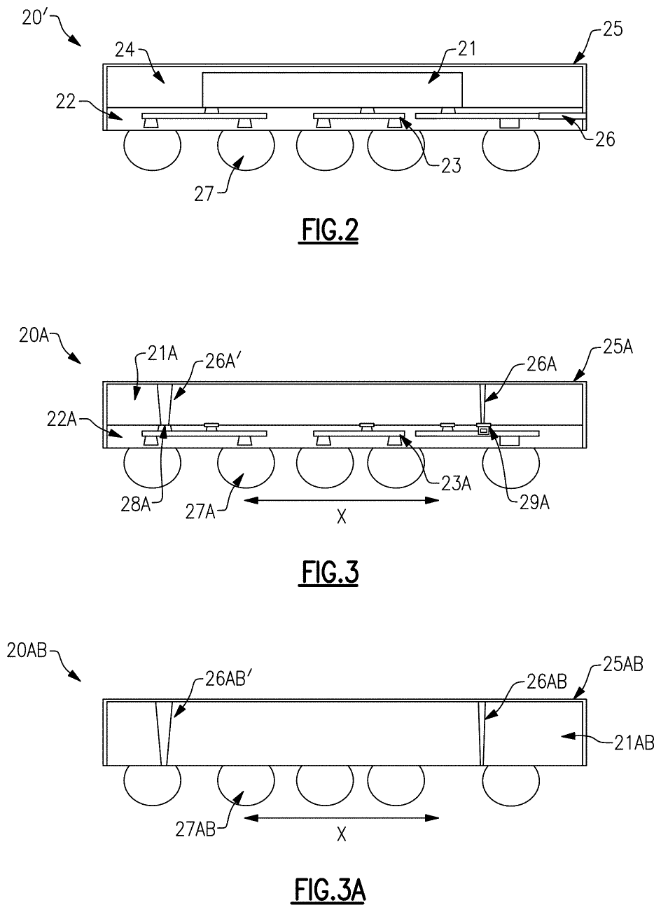

FIG. 2 shows one implementation of a shielded wafer level chip scale package (sWLCSP) 20′ (hereafter the “shielded package”). The shielded package 20′ includes a die 21 disposed on a substrate (e.g., silicon substrate, dielectric substrate) 22. The substrate 22 includes one or more redistribution layers (RDL) (e.g., metal traces, copper traces) 23 that connect to the die 21 and to solder connections (or interconnect members) 27 on an underside of the substrate 22. A mold 24 is disposed over the die 21. In the illustrated implementation, a shield 25 is disposed over the mold 24 (e.g., to circumscribe, encapsulate, surround or otherwise cover the mold 24, and thereby cover the die 21 and completely enclose the mold 24). The shield 25 can extend over a top of the mold 24 and die 21, and over a side of the mold 24 and be in contact with a periphery or boundary (e.g., a side surface, peripheral surface, outer boundary) of the substrate 22. The shield 25 can be made of a metal (e.g., aluminum (Al)). The shield 25 can in one implementation be applied over the mold 24 using a sputter process. In another implementation, the shield 25 can in one implementation be applied over the mold 24 using a spray process. As shown in FIG. 2, the shield 25 is connected to the redistribution layer(s) 23 by a ground connection 26. The ground connection 26 can be an extension of the redistribution layer(s) 23 that allow the shield 25 (e.g., a side of the shield) to be connected to ground (e.g., via the ground connection 26, redistribution layer(s) 23 and solder connections or interconnect members 27). Further, the design of ground connections 26 can facilitate its use as a thermal connection to a topside mounted heat sink thermally connected to the shield 25. Advantageously, the shield 25 shields the package 20′ from EM interference from other components. Additionally, the shield 25 can inhibit (e.g., prevent) stray power or stray EM radiation from getting into the package 20′. In one implementation, the package 20′ can be used for power amplifiers. In another implementation, if the package 20′ is a very low noise device, the shield 25 can protect the package 20′ from external radiation.

FIG. 3 shows a schematic view of a shielded wafer level chip scale package (sWLCSP) 20A (hereafter the “shielded package”). Some of the features of the shielded package 20A are similar to features of the shielded package 20′ in FIG. 2. Thus, reference numerals used to designate the various components of the shielded package 20A are identical to those used for identifying the corresponding components of the shielded package 20′ in FIG. 2, except that an “A” has been added to the numerical identifier. Therefore, the structure and description for the various features of the shielded package 20′ in FIG. 2 are understood to also apply to the corresponding features of the shielded package 20A in FIG. 3, except as described below. Though the features below are described in connection with the shielded package 20A, the features also apply to (e.g., could be combined with the features in) all shielded packages disclosed herein.

The shielded package 20A differs from the shielded package 20′ in that the mold 24 is excluded and the die 21A substantially extends along (e.g., matches, coincides with) the length (in the X direction) and depth (in the Y direction into the page in FIG. 3) of the substrate 22A. Additionally, the shielded package 20A excludes a ground connection that connects from the side of the shield 25A to the redistribution layer(s) 23. Rather, the shielded package 20A can have one or more vias (e.g., through substrate vias or TSVs) 26A, 26A′ that extend through the die 21A and interconnect the shield 25A and the redistribution layer(s) 23A. The shield 25A can therefore be grounded via the vias 26A, 26A′, redistribution layer(s) 23A and solder connections (e.g. interconnect members) 27A. In one example, one or more of the vias, such as via 26A′, can be relatively narrower and connect to fab metal portions 29A that connect to the redistribution layer(s) 23A. The fab metal portions 29A can provide a wider or larger area interface for the via 26A. In another example, one or more of the vias, such as via 26A, can be relatively wider and connect directly to the redistribution layer(s) 23A. Advantageously, the TSVs 26A, 26A′, in addition to providing a ground connection for the shield 25A, also dissipate heat from the shield 25A through the redistribution layer(s) 23A and solder connections (interconnect members) 27A. This can be advantageous when the circuitry of the die 21A generates a lot of power and/or generates a lot of heat (e.g., a power amplifier).

FIG. 3A shows a schematic view of a shielded wafer level chip scale package (sWLCSP) 20AB (hereafter the “shielded package”). Some of the features of the shielded package 20AB are similar to features of the shielded package 20A in FIG. 3. Thus, reference numerals used to designate the various components of the shielded package 20AB are identical to those used for identifying the corresponding components of the shielded package 20A in FIG. 3, except that a “B” has been added to the numerical identifier (e.g., 20AB instead of 20A). Therefore, the structure and description for the various features of the shielded package 20A in FIG. 3, which are based on the structure and description of features of the shielded package 20′ in FIG. 2, are understood to also apply to the corresponding features of the shielded package 20AB in FIG. 3A, except as described below. Though the features below are described in connection with the shielded package 20AB, the features also apply to (e.g., could be combined with the features in) all shielded packages disclosed herein.

The shielded package 20AB differs from the shielded package 20A in that it does not include a substrate or redistribution layers (e.g., like substrate 22A and redistribution layers 23A). Rather, the vias (e.g., through substrate vias or TSVs) 26AB, 26AB′ extend through the die 21AB and electrically connect the shield 25AB with the interconnect members (e.g., solder connections, solder balls) 27AB to thereby ground the shield 25AB.

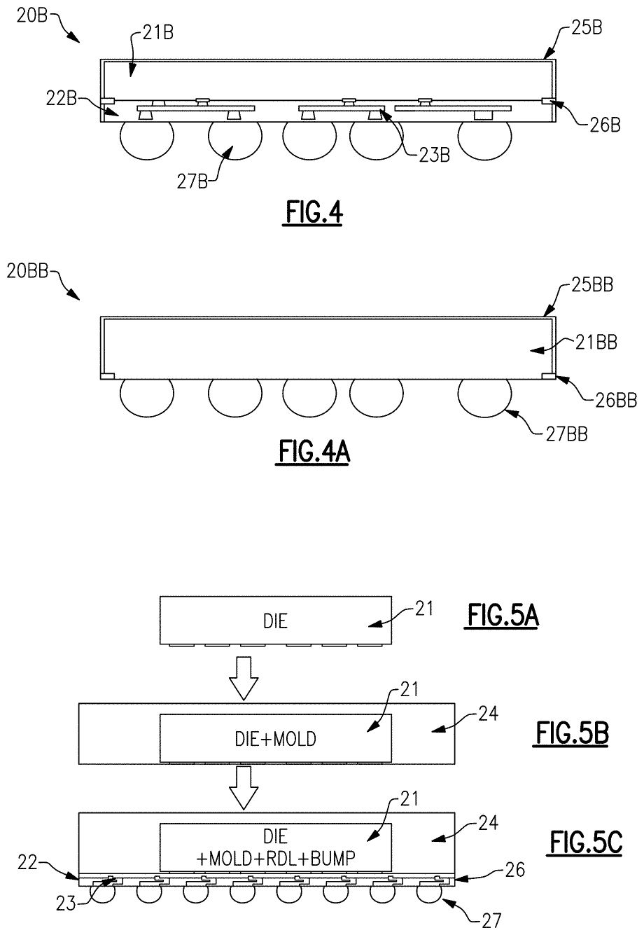

FIG. 4 shows a schematic view of a shielded wafer level chip scale package (sWLCSP) 20B (hereafter the “shielded package”). Some of the features of the shielded package 20B are similar to features of the shielded package 20′ in FIG. 2. Thus, reference numerals used to designate the various components of the shielded package 20B are identical to those used for identifying the corresponding components of the shielded package 20′ in FIG. 2, except that a “B” has been added to the numerical identifier. Therefore, the structure and description for the various features of the shielded package 20′ in FIG. 2 are understood to also apply to the corresponding features of the shielded package 20B in FIG. 4, except as described below. Though the features below are described in connection with the shielded package 20B, the features also apply to (e.g., could be combined with the features in) all shielded packages disclosed herein.

The shielded package 20B differs from the shielded package 20′ in that the mold 24 is excluded and the die 21B substantially extends along (e.g., matches, coincides with) the length (in the X direction) and depth (in the Y direction into the page in FIG. 4) of the substrate 22B. Additionally, instead of a ground connection 26A that extend from (e.g., is an extension of) the redistribution layer(s) 23A to the shield 25A, a seal ring 26B connects to the shield 25B to foundry metal layers (e.g., in the substrate 22B). For example, the seal ring 26B connects to the shield 25B along a periphery of the shield 25B and extends inward therefrom.

FIG. 4A shows a schematic view of a shielded wafer level chip scale package (sWLCSP) 20BB (hereafter the “shielded package”). Some of the features of the shielded package 20BB are similar to features of the shielded package 20B in FIG. 4. Thus, reference numerals used to designate the various components of the shielded package 20BB are identical to those used for identifying the corresponding components of the shielded package 20B in FIG. 4, except that a “B” has been added to the numerical identifier (e.g., 20BB instead of 20B). Therefore, the structure and description for the various features of the shielded package 20B in FIG. 4, which are based on the structure and description of features of the shielded package 20′ in FIG. 2, are understood to also apply to the corresponding features of the shielded package 20BB in FIG. 4A, except as described below. Though the features below are described in connection with the shielded package 20BB, the features also apply to (e.g., could be combined with the features in) all shielded packages disclosed herein.

The shielded package 20BB differs from the shielded package 20B in that it does not include a substrate or redistribution layers (e.g., like substrate 22B and redistribution layers 23B). Rather, the a seal ring 26BB connects to the shield 25BB to the interconnect members (e.g., solder connections, solder balls) 27BB via the die 21BB (e.g., via foundry metal layers in the die 21BB) to thereby ground the shield 25BB. For example, the seal ring 26Bb connects to the shield 25Bb along a periphery of the die 21BB and extends inward therefrom.

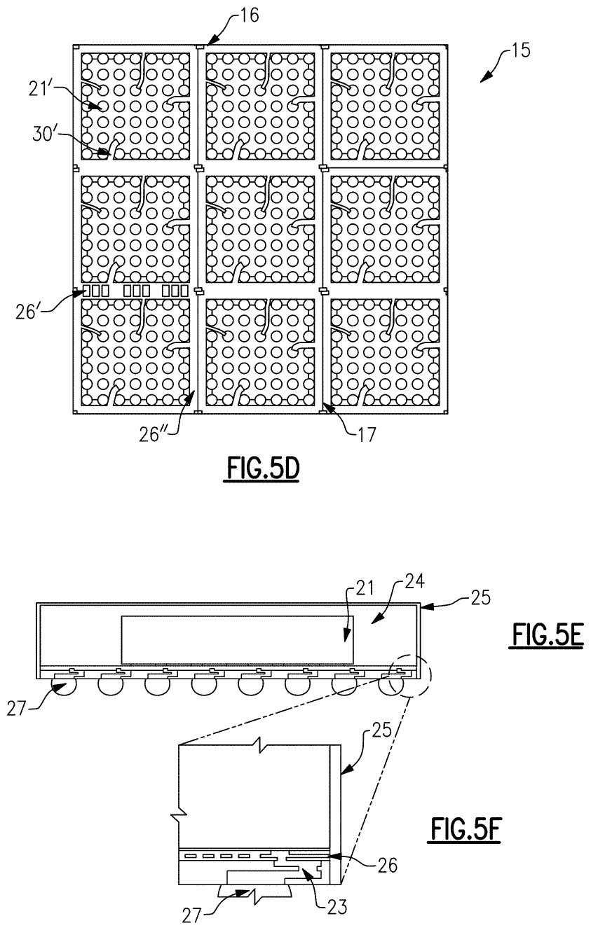

FIGS. 5A-5F show different steps in a process for manufacturing the shielded package 20′ (e.g. shown in FIG. 2). With reference to FIGS. 5A, the process includes forming or providing the die 21, forming the mold 24 over the die 21, and attaching the mold 24 and die 21 to a top side of the substrate 22 that has one or more redistribution layers 23 and solder connections (interconnect members) 27 attached to an underside of the substrate 22. The redistribution layer(s) 23 include a ground connection 26 that extends to the edge of the substrate 22 (e.g., into the street of the wafer, as further discussed below).

With reference to FIG. 5D, a wafer 15 includes multiple dies 21′ (prior to completion of a shielding process), where the wafer 15 can be diced along the streets 16 of the wafer 15 to separate the individual dies 21′. In one implementation, the ground connection is a continuous (metal) strip 26″ that extends past an edge of the die 21′ and connects with ground connections 30′ that connect to the interior of the die 21′. The continuous (metal) strips 26″ adjacent opposite dies 21′ can be separated by a strip or line 17 of mold material. In another implementation, the ground connection is provide by segmented (e.g., separate, spaced apart) metal strips 26′ that extend between adjacent dies 21′ and can be cut when the wafer 15 is diced. The ground connection 26 in FIG. 5C can be a continuous strip 26; or a segmented strips 26′.

FIGS. 5E-5F show additional steps in the process for manufacturing the shielded package 20′. The shield 25 is applied over the mold 24 so that it surrounds, encapsulates or otherwise covers the mold 24 and die 21, and so that the shield 25 contacts the ground connection 26 to connect the shield 25 to ground (e.g., via the ground connection 26, redistribution layer(s) 23 and solder connections (or interconnect members) 27.

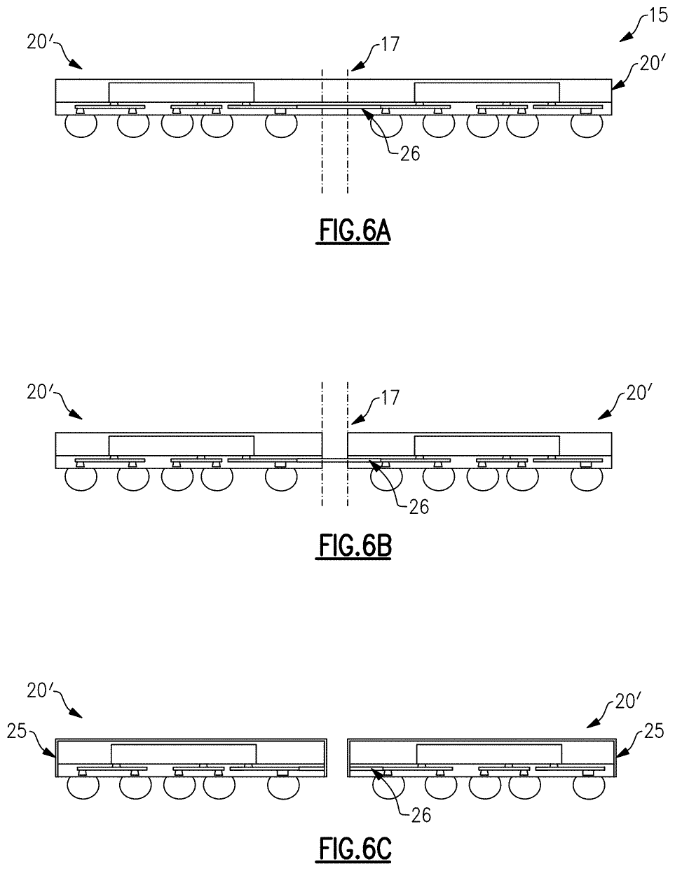

FIGS. 6A-6C show steps in a process for manufacturing the shielded package 20′ (e.g., shown in FIG. 2). FIG. 6A shows the wafer with multiple (e.g., two) packages 20′ (prior to shielding) separated by a dicing street 17 along which the wafer 15 is cut (as shown in FIG. 6B) to separate the packages 20′ from the wafer 15. The wafer 15 is diced (e.g., with a saw) so that the street 17 and the ground connection 26 is cut, resulting in an exposed portion of the ground connection 26 that can contact the shield 25A. FIG. 6C shows the shield 25A applied to the package 20′ so that the shield 25 contacts the ground connection 26 to connect the shield 25 to ground (e.g., via the ground connection 26, redistribution layer(s) 23 and solder connections (or interconnect members) 27.

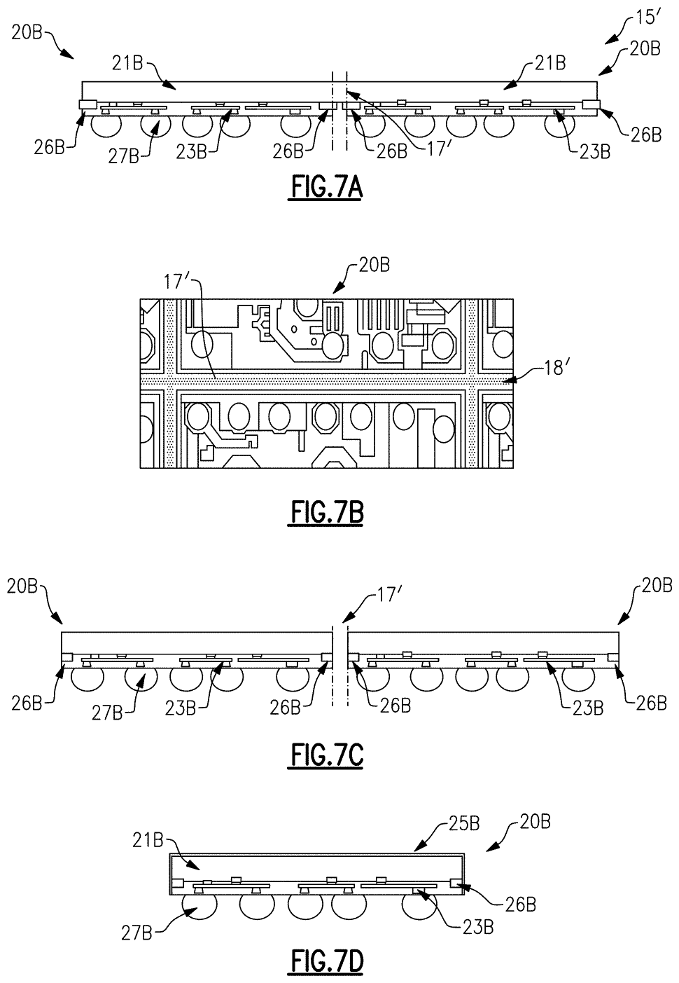

FIG. 7A-7D show steps in a process for manufacturing the shielded package 20B (e.g., as shown in FIG. 4). FIG. 7A shows the wafer 15′ with multiple (e.g., two) packages 20B (prior to shielding) separated by a dicing street 17′ along which the wafer 15′ is cut (as shown in FIG. 7C) to separate the packages 20B from the wafer 15′. FIG. 7B shows a top view of the street 17′ with metal coupons 18′ (e.g., foundry metal). The wafer 15′ is diced (e.g., with a saw) so that the street 17 and the seal ring 26B is cut, resulting in an exposed portion of the seal ring 26B that can contact the shield 25B. FIG. 7C shows the shield 25B applied to the package 20B so that the shield 25B contacts the seal ring 26B to connect the shield 25B to ground (e.g., via the seal ring 26B, foundry metal, redistribution layer(s) 23B and solder connections (or interconnect members) 27B.

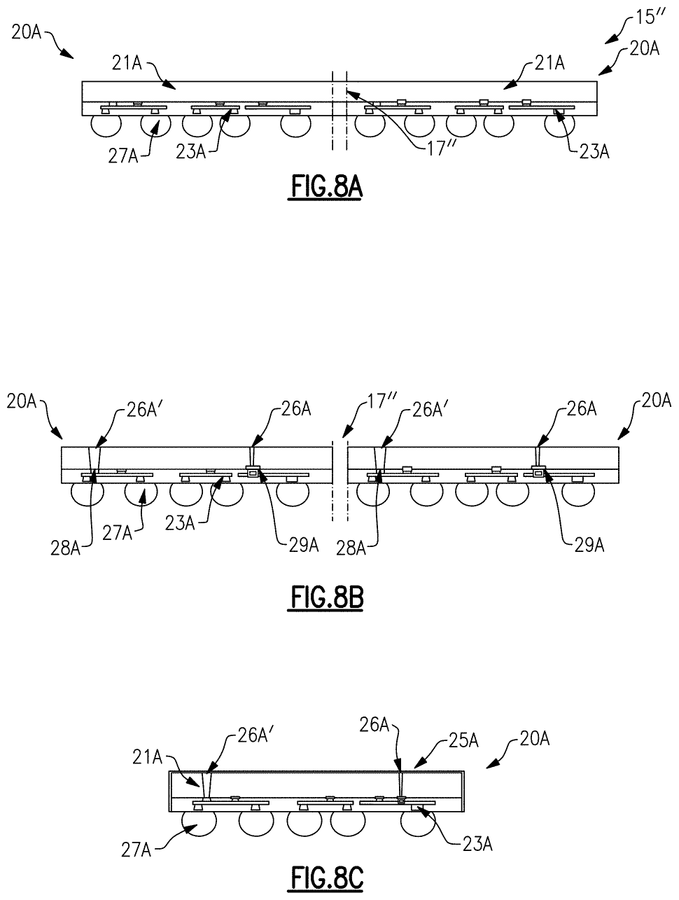

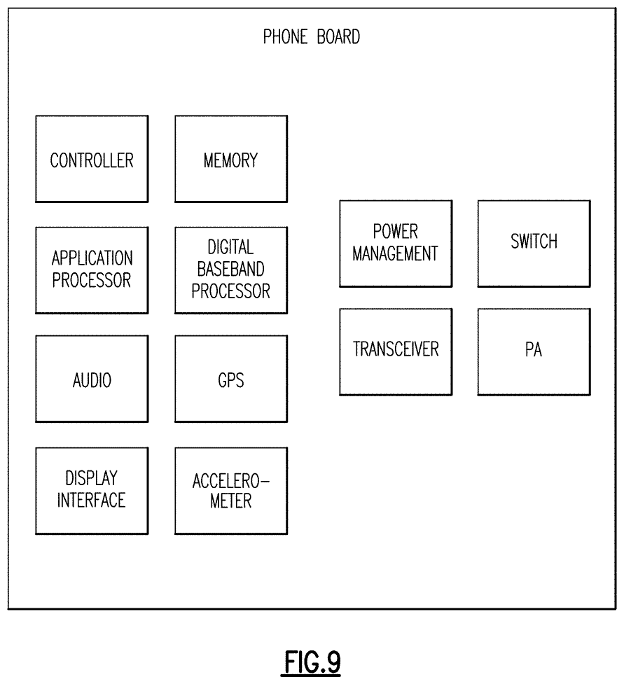

FIG. 8A-8C show steps in a process for manufacturing the shielded package 20A (e.g., as shown in FIG. 3). FIG. 8A shows the wafer 15″ with multiple (e.g., two) packages 20A (prior to shielding) separated by a dicing street 17″ along which the wafer 15″ is cut (as shown in FIG. 8C) to separate the packages 20A from the wafer 15″. The vias 26A, 26A′ can be formed (e.g., etched) through the die 21A prior to dicing the wafer 15″ (e.g., with a saw) along the street 17″, as shown in FIG. 8B. FIG. 8C shows the shield 25A applied to the package 20A so that the shield 25A contacts the vias 26A, 26A′ to connect the shield 25A to ground (e.g., via the redistribution layer(s) 23A and interconnect members (e.g., solder connections, solder balls) 27A.

FIG. 9 shows that in some embodiments, one or more modules included in a circuit board such as a wireless phone board can include one or more shielded wafer level chip scale packaging features as described herein. Non-limiting examples of modules that can benefit from such packaging features include, but are not limited to, a controller module, an application processor module, an audio module, a display interface module, a memory module, a digital baseband processor module, a global positioning system (GPS) module, an accelerometer module, a power management module, a transceiver module, a switching module, and a power amplifier module.

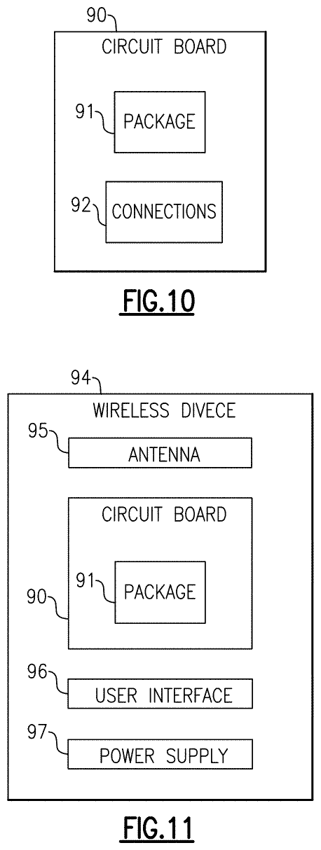

FIG. 10 schematically depicts a circuit board 90 having a shielded wafer level chip scale package 91 mounted thereon. The circuit board 90 can also include other features such as a plurality of connections 92 to facilitate operations of various packages mounted thereon. FIG. 11 schematically depicts a wireless device 94 (e.g., a cellular phone) having a circuit board 90 (e.g., a phone board). The circuit board 90 is shown to include a shielded wafer level chip scale package 91 having one or more features as described herein. The wireless device is shown to further include other components, such as an antenna 95, a user interface 96, and a power supply 97.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kilohertz (kHz) to 300 gigahertz (GHz), such as in a frequency range from about 450 MHz to 8.5 GHz and 24 GHz to 60 GHz. An acoustic wave resonator including any suitable combination of features disclosed herein be included in a filter arranged to filter a radio frequency signal in a fifth generation (5G) New Radio (NR) operating band within Frequency Range 1 (FR1). A filter arranged to filter a radio frequency signal in a 5G NR operating band can include one or more acoustic wave resonators disclosed herein. FR1 can be from 410 MHz to 7.125 GHz, for example, as specified in a current 5G NR specification. FR2 can be between 24.25 GHz to 52.6 GHz. One or more acoustic wave resonators in accordance with any suitable principles and advantages disclosed herein can be included in a filter arranged to filter a radio frequency signal in a fourth generation (4G) Long Term Evolution (LTE) operating band and/or in a filter with a passband that spans a 4G LTE operating band and a 5G NR operating band.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Any of the embodiments described above can be implemented in association with mobile devices such as cellular handsets. The principles and advantages of the embodiments can be used for any systems or apparatus, such as any uplink cellular device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals having a frequency in a range from about 30 kHz to 300 GHz, such as a frequency in a range from about 450 MHz to 8.5 GHz.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An electronics package for use in a module of an electronic device comprising:
a die;
a plurality of interconnect members disposed under the die;
one or more vias that extend through the die and are electrically and thermally connected to one of more of the interconnect members; and
a metal shield disposed over the die, the metal shield in contact with a peripheral boundary of the die and connected to ground via the one or more vias and the interconnect members, the metal shield configured to shield the die from stray power and electromagnetic radiation.

2. The package of claim 1 further comprising a substrate interposed between the die and the interconnect members, the substrate comprising one or more redistribution layers, the one or more vias electrically and thermally connected to one or more of the interconnect members via the one or more redistribution layers.

3. The package of claim 1 wherein the one or more vias are configured to dissipate heat from the metal shield and the die.

4. The package of claim 2 wherein at least one of the one or more vias connects to at least one of the one or more redistribution layers via a fab metal connection.

5. The package of claim 1 wherein at least one of the one or more vias has a narrower profile than another of the one or more vias.

6. The package of claim 2 wherein the die extends along an area that substantially coincides with an area of the substrate.

7. A module for an electronic device comprising:
a package substrate;
an electronics package mounted on the package substrate, the electronics package including a die, a plurality of interconnect members disposed under the die, one or more vias that extend through the die and are electrically and thermally connected to one of more of the interconnect members, and a metal shield disposed over the die, the metal shield in contact with a peripheral boundary of the die and connected to ground via the one or more vias and the interconnect members, the metal shield configured to shield the die from stray power and electromagnetic radiation, the electronics package mounted to the package substrate via the interconnect members; and
additional circuitry, the electronics package and the additional circuitry disposed on the package substrate.

8. The module of claim 7 further comprising a substrate interposed between the die and the interconnect members, the substrate comprising one or more redistribution layers, the one or more vias electrically and thermally connected to one or more of the interconnect members via the one or more redistribution layers.

9. The module of claim 7 wherein the one or more vias are configured to dissipate heat from the metal shield and the die.

10. The module of claim 8 wherein at least one of the one or more vias connects to at least one of the one or more redistribution layers via a fab metal connection.

11. The module of claim 7 wherein at least one of the one or more vias has a narrower profile than another of the one or more vias.

12. The module of claim 8 wherein the die extends along an area that substantially coincides with an area of the substrate.

13. The module of claim 7 wherein the metal shield is in contact with a top of the die.

14. A wireless electronic device comprising:
an antenna; and
a front end module including one or more electronics packages, each electronics package including a die, a plurality of interconnect members disposed under the die, one or more vias that extend through the die and are electrically and thermally connected to one of more of the interconnect members, and a metal shield disposed over the die, the metal shield in contact with a peripheral boundary of the die and connected to ground via the one or more vias and the interconnect members, the metal shield configured to shield the die from stray power and electromagnetic radiation.

15. The wireless electronic device of claim 14 further comprising a substrate interposed between the die and the interconnect members, the substrate comprising one or more redistribution layers, the one or more vias electrically and thermally connected to one or more of the interconnect members via the one or more redistribution layers.

16. The wireless electronic device of claim 14 wherein the one or more vias are configured to dissipate heat from the metal shield and the die.

17. The wireless electronic device of claim 15 wherein at least one of the one or more vias connects to at least one of the one or more redistribution layers via a fab metal connection.

18. The wireless electronic device of claim 14 wherein at least one of the one or more vias has a narrower profile than another of the one or more vias.

19. The wireless electronic device of claim 15 wherein the die extends along an area that substantially coincides with an area of the substrate.

20. The wireless electronic device of claim 14 wherein the metal shield is in contact with a top of the die.
